(19) United States
(12) Patent Application Publication
(10) Pub. No.: US 2006/0246323 A1
(43) Pub. Date: Nov. 2, 2006

(54) Epitaxially grown non-oxide magnetic layers for granular perpendicular magnetic recording media applications

(75) Inventors: Connie Chunling Liu, San Jose, CA (US); Qixu Chen, Milpitas, CA (US); Shanghsien Rou, Fremont, CA (US); Kueir-Weei Chour, San Jose, CA (US); Romulo Canilon Ata, San Jose, CA (US); Kuo Hsing Hwang, San Jose, CA (US)

Correspondence Address: MORRISON & FOERSTER LLP, 1650 TYSONS BOULEVARD, SUITE 300, MCLEAN, VA, 22102, US

(73) Assignee: SEAGATE TECHNOLOGY LLC, Scotts Valley, CA (US)

(21) Appl. No.: 11/115,331

(22) Filed: Apr. 27, 2005

(51) Int. Cl. G11B 5/66; C23C 14/00

(52) U.S. Cl. 428/829; 428/836.2; 428/836.3; 204/192.2

(57) ABSTRACT

A magnetic recording medium having a substrate, a first magnetic layer having a perpendicular anisotropy and a second magnetic layer having a perpendicular anisotropy, wherein the second magnetic layer contains substantially no dielectric material, (such as, but not limited to, oxides, carbides, and nitrides) is disclosed. Also disclosed is a method for manufacturing the magnetic recording medium of the embodiments of this invention.

### FIELD OF INVENTION

This invention relates to magnetic recording media, such as thin film magnetic recording disks, and to a method of manufacturing the media. The invention has particular applicability to high areal density perpendicular magnetic recording media having a two or more magnetic layers having perpendicular anisotropy, wherein at least one magnetic layer contains substantially no dielectric material (such as, but not limited to, oxides, carbides, and nitrides).

### BACKGROUND

Magnetic thin-film media, wherein a fine grained polycrystalline magnetic alloy layer serves as the active recording medium layer, are generally classified as “longitudinal” or “perpendicular,” depending on the orientation of the magnetization of the magnetic domains of the grains of the magnetic material. In longitudinal media (also often referred as “conventional” media), the magnetization in the bits is flipped between lying parallel and anti-parallel to the direction in which the head is moving relative to the disc.

Perpendicular magnetic recording media are being developed for higher density recording as compared to longitudinal media. The thin-film perpendicular magnetic recording medium comprises a substrate and a magnetic layer having perpendicular magnetic anisotropy. In perpendicular media, the magnetization of the disc, instead of lying in the disc's plane as it does in longitudinal recording, stands on end perpendicular to the plane of the disc. The bits are then represented as regions of upward or downward directed magnetization (corresponding to the 1's and 0's of the digital data).

FIG. 1 shows a disk recording medium and a cross section of a disc showing the difference between longitudinal and perpendicular magnetic recording. Even though FIG. 1 shows one side of the disk, magnetic recording layers are usually sputter deposited on both sides of the non-magnetic aluminum substrate of FIG. 1. Also, even though FIG. 1 shows an aluminum substrate, other embodiments include a substrate made of glass, glass-ceramic, aluminum/NiP, metal alloys, plastic/polymer material, ceramic, glass-polymer, composite materials or other non-magnetic materials.

While perpendicular media technology provides higher areal density capability over longitudinal media, granular perpendicular magnetic recording media is being developed for further extending the areal density as compared to conventional (non-granular) perpendicular magnetic recording which is limited by the existence of strong lateral exchange coupling between magnetic grains. Granular structure provides better grain isolation through oxide segregation to grain boundary, hence enhancing grain to grain magnetic decoupling and increasing media signal to noise ratio (SNR).

A granular perpendicular magnetic layer contains magnetic columnar grains separated by grain boundaries comprising a dielectric material such as oxides, nitrides or carbides to decouple the magnetic grains. The grain boundaries having a thickness of about 2 Å to about 30 Å, provide a substantial reduction in the magnetic interaction between the magnetic grains. In contrast to conventional perpendicular media, wherein the longitudinal magnetic layer is typically sputtered at low pressures and high temperatures in the presence of an inert gas, such as argon (Ar), deposition of the granular perpendicular magnetic layer is conducted at relatively high pressures and low temperatures and utilizes a reactive sputtering technique wherein oxygen (O₂), CₓH_{y}, and/or nitrogen (N₂) are introduced in a gas mixture of, for example, Ar and O₂, Ar and CₓH_{y} Ar and N₂, or Ar and O₂, CₓH_{y} and N₂. Alternatively, oxide, carbide or nitrides may be introduced by utilizing a sputter target comprising oxides, carbides and/or nitrides which is sputtered in the presence of an inert gas (e.g., Ar), or, optionally, may be sputtered in the presence of a sputtering gas comprising O₂, CₓH_{y}, and/or N₂ with or without the presence of an inert gas. Not wishing to be bound by theory, the introduction of O₂, CₓH_{y}, and/or N₂ reactive gases, and oxides, carbides, and/or nitrides inside targets provides oxides, carbides, and/or nitrides that migrate into the grain boundaries, thereby providing a granular perpendicular structure having a reduced lateral exchange coupling between grains.

FIG. 2 illustrates a granular perpendicular magnetic recording medium design of the prior art. However, this kind of design suffers from the drawbacks such as following: (1) Difficulty to balance coupling/decoupling among the magnetic grains; thus, usually high decoupling is needed to achieve better performance which will result in non-squared loop and high dynamic Hcr. (2) Poor manufacturability due to reactive sputtering with oxygen to achieve oxide grain boundary. (3) High media defects from oxide particles and poor uniformity associated with reactive sputtering. (4) Poor mechanical performance (especially corrosion performance) due to porous oxide grain boundary and rougher media surface. (5) Migration of oxides and/or nitrides under low atomic mobility deposition (i.e., low temperature deposition), as well as the shadowing effect of the high gas pressure reactive sputter process, produces a granular magnetic layer having a porous structure significantly more susceptible to corrosion.

On the other hand, even though a longitudinal recording medium typically has a lower areal density than a granular perpendicular magnetic recording medium, it is substantially free of the defects of the granular perpendicular magnetic recording medium mentioned above. This there is a need to develop a magnetic recording medium having perpendicular anisotropy, yet being substantially free of the defects of the granular perpendicular magnetic recording medium.

### SUMMARY OF THE INVENTION

This invention relates to a perpendicular magnetic recording medium comprising: a substrate, a first magnetic layer comprising a dielectric material at a grain boundary and having a perpendicular anisotropy, and a second magnetic layer having a perpendicular anisotropy, wherein the second magnetic layer contains substantially no oxide. Preferably, the dielectric material is selected from the group consisting of an oxide, carbide, carbon, a nitride and combinations thereof. Preferably, the second magnetic layer comprises a grain boundary that is thinner than the grain boundary of the first magnetic layer. Preferably, the first magnetic layer comprises Co_{100-x-y-z}Ptₓ(X)_{y}(MO)_{z}, wherein X comprises Cr; MO is an oxide; and ranges of x, y and z are: 1≦x≦30, 0≦y≦30 and 1≦z≦30. Preferably, MO is selected from the group consisting of SiO₂, TiO₂, Nb₂O₅, WO₃, Al₂O₃, and combinations thereof. Preferably, the second magnetic layer comprises Co_{100-x-y-z-α}CrₓPt_{y}B_{z}Y_{α}, wherein X is an optional additive selected from the group consisting of Cu, Au, Ta, V and combinations thereof, and ranges of x, y, z and a are: 0≦x≦30, 0≦y≦30, 0≦z≦30, 0≦α≦10. Preferably, the first magnetic layer comprises a single layer or multiple layers. Preferably, the second magnetic layer comprises a single layer or multiple layers. Preferably, the second magnetic layer c comprises a grain boundary that is denser than the grain boundary of the first magnetic layer. Preferably, the grain boundary of the second magnetic layer comprises a material selected from the group consisting of Co, Pt, Cr, B and combinations thereof. Preferably, the second magnetic layer is directly on top of the first magnetic layer.

In one variation, the recording could further comprise a soft underlayer between the substrate and the first magnetic layer. In another variations, the recording medium could further comprise a seedlayer and/or interlayer that grow the first magnetic layer in a Co (00.2) orientation. Preferably, the second magnetic layer has a growth orientation that is same as a growth orientation of the first magnetic layer. Preferably, the first magnetic layer has a thickness t, and the second magnetic layer has a thickness t₂, and wherein the magnetic recording medium has a higher SNR than that of another magnetic recording medium having same structure except the first magnetic layer has a thickness t₁+t₂ and the second magnetic layer has a thickness of zero.

Another embodiment is a method of manufacturing a magnetic recording medium, comprising depositing a first magnetic layer having a perpendicular anisotropy and depositing a second magnetic layer having a perpendicular anisotropy on the first magnetic layer from a target containing substantially no oxide. Preferably, said depositing the first magnetic layer is in an argon and oxygen containing environment having a pressure of more than 20 mTorr and said depositing the second magnetic layer is in an argon containing environment having substantially no oxygen and having a pressure of less than 20 mTorr. Preferably, the first magnetic layer is deposited from one or more targets comprising an oxide. Preferably, the second magnetic layer contains substantially no oxide.

Additional advantages of this invention will become readily apparent to those skilled in this art from the following detailed description, wherein only the preferred embodiments of this invention is shown and described, simply by way of illustration of the best mode contemplated for carrying out this invention. As will be realized, this invention is capable of other and different embodiments, and its details are capable of modifications in various obvious respects, all without departing from this invention. Accordingly, the drawings and description are to be regarded as illustrative in nature and not as restrictive.

### BRIEF DESCRIPTION OF THE DRAWINGS

FIG. 1 schematically shows a magnetic disk recording medium comparing longitudinal and perpendicular magnetic recording.

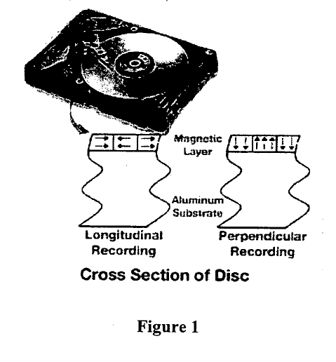

FIG. 2 shows a prior art granular perpendicular magnetic recording medium.

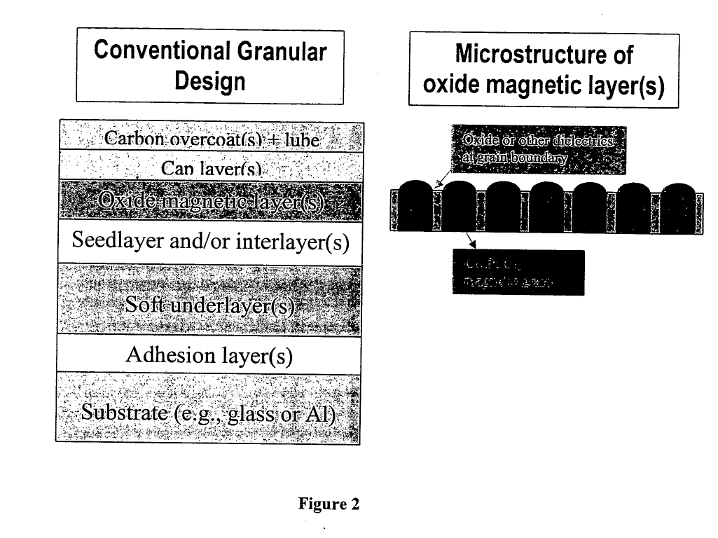

FIG. 3 shows a novel perpendicular magnetic recording medium according to an embodiment of this invention.

FIG. 4 shows XRD spectra of a conventional media having M1 and an embodiment of the claimed media having M+M2.

FIG. 5 shows FE-EFL and Med eSNR gain of an embodiment of the claimed media and a conventional media having M1.

### DETAILED DESCRIPTION

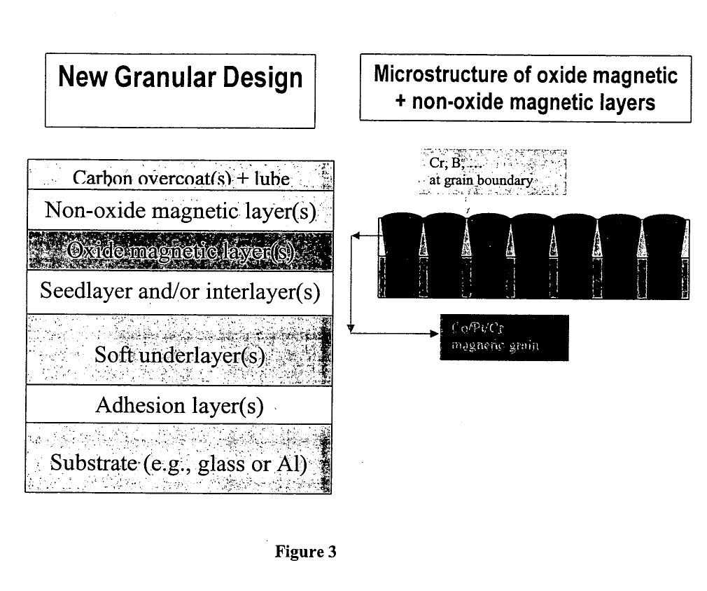

This invention relates to a perpendicular magnetic recording medium having a substrate, soft underlayer(s), seed layer(s), interlayer(s), and a magnetic recording layer comprising grains. FIG. 3 is an embodiment of this invention showing a perpendicular magnetic recording medium comprising an oxide magnetic layer (M1) to maximize grain to grain magnetic decoupling and a non-oxide magnetic layer (M2) to optimize coupling for higher squareness and lower dynamic Hcr. M1 could be sputter deposited under condition for manufacturing a perpendicular magnetic layer, i.e., typically under a high pressure of greater than 20 millitorr in an argon and oxygen containing chamber.

The layer M2 does not include any dielectric additive such as oxide, nor reactive sputtering with oxygen. The layer M2 could be sputtered from a target under low pressure of less than 20 millitorr in an argon-containing chamber, i.e., conditions similar to that used for manufacturing a longitudinal magnetic recording layer wherein typically B and/or Cr is at the grain boundary.

Even though the two or more magnetic layered media of this invention has one or more layers, e.g., M2, formed by a process similar to that used for manufacturing a longitudinal magnetic layer, it was unexpectedly found by this invention that M2 has perpendicular anisotropy with c-axis normal to substrate surface. This could be due to epitaxial growth of M2 following the crystallographic orientation of the dielectric-containing magnetic M1. The grain boundary of M1 could contain additives such as Cr and/or B similar to that of longitudinal media. Thus, the grain boundary could be thinner and denser than the dielectric-containing grain boundary of a perpendicular magnetic recording layer. As a result, the magnetic design of this invention provides considerable flexibility with endless choices of magnetic alloys for the formation of the perpendicular magnetic recording layers. In addition, the magnetic design of this invention could provide improved manufacturability, lower defects in the magnetic recording media, better mechanical performance, and above all, a tremendous potential of Bit Error Rate (BER) improvement. The examples discussed below also unexpectedly show up to two decades improvement in signal-to-noise ratio (SNR) over a perpendicular magnetic recording media having the conventional granular oxide media design.

All samples of the granular media disclosed here were fabricated with Intevac MDP 250 B+ sputter machine on Al substrates, optionally having a NiP-coating. The multilayer films were deposited under ambient temperature with DC (direct current) magnetron sputtering and/or RM (rotation magnets) sputtering except for the carbon overcoats were deposited with ion beam deposition. An embodiment of the media comprises, from the bottom to the top:

(1) Substrate: polished glass, glass ceramics, or Al/NiP.

(2) Adhesion layers to ensure strong attachment of the functional layers to the substrates. One can have more than one layer for better adhesion or skip this layer if adhesion is fine. The examples include Ti alloys.

(3) Soft underlayers (SUL) include various design types, including a single SUL, anti-ferromagnetic coupled (AFC) structure, laminated SUL, SUL with pinned layer (also called anti-ferromagnetic exchange biased layer), and so on. The examples of SUL materials include FeₓCo_{y}B_{z} based, and CoₓZr_{y}Nb_{z}/CoₓZr_{y}Ta_{z} based series.

(4) Seed layer(s) and interlayer(s) are the template for Co (00.2) growth. Examples are RuX series of materials.

(5) Oxide containing magnetic layers (M1) can be sputtered with conventional granular media targets reactively (with Oₓ) and/or non-reactively. Multiple layers can be employed to achieve desired film property and performance. Examples of targets are Co_{100-x-y}Ptₓ(MO)_{y} and/or Co_{100-x y-z}Ptₓ(X)_{y}(MO)_{z} series (X is the 3^{id} additives such as Cr, and M is metal elements such as Si, Ti and Nb). Besides oxides in M1, the list can be easily extended such that the magnetic grains in M1 can be isolated from each other with dielectric materials at grain boundary, such as nitrides (MₓN_{y}), carbon (C) and carbides (MₓC_{y}). The examples of sputter targets are Co_{100-x-y}Ptₓ(MN)_{y}, Co_{100-x-y}Ptₓ(MC)_{y} and/or Co_{100-x-y-z}Ptₓ(X)_{y}(M)_{z}, Co_{100-x-y-z}Ptₓ(X)_{y}(MC)_{z} series.

(6) Non-oxide containing magnetic layers (M2): The sputter targets can be used including conventional longitudinal media alloys and/or alloy perpendicular media. Desired performance will be achieved without reactive sputtering. Single layer or multiple layers can be sputtered on the top of oxide containing magnetic layers. The non-oxide magnetic layer(s) will grow epitaxially from oxide granular layer underneath. The orientation could eventually change if these layers are too thick. The examples of these are Co_{100-x-y-z-α}CrₓPt_{y}B_{z}X_{α}Y_{β}.

(7) Cap layer, which is optional for this design. In one variation, with dense grains and grain boundary without oxygen may not be necessary. Conventional carbon and lubrication can be adapted for the embodiment of the claimed media to achieve adequate mechanical performance.

The above layered structure of an embodiment is an exemplary structure. In other embodiments, the layered structure could be different with either less or more layers than those stated above.

Instead of the optional NiP coating on the substrate, the layer on the substrate could be any Ni-containing layer such as a NiNb layer, a Cr/NiNb layer, or any other Ni-containing layer. Optionally, there could be an adhesion layer between the substrate and the Ni-containing layer. The surface of the Ni-containing layer could be optionally oxidized.

The substrates used can be Al alloy, glass, or glass-ceramic. The magnetically soft underlayers according to present invention are amorphous or nanocrystalline and can be FeCoB, FeCoC,FeCoTaZr, FeTaC, FeSi, CoZrNb, CoZrTa, etc. The seed layers and interlayer can be Cu, Ag, Au, Pt, Pd, Ru-alloy, etc. The CoPt-based magnetic recording layer can be CoPt, CoPtCr, CoPtCrTa, CoPtCrB, CoPtCrNb, CoPtTi, CoPtCrTi, CoPtCrSi, CoPtCrAl, CoPtCrZr, CoPtCrHf, CoPtCrW, CoPtCrC, CoPtCrMo, CoPtCrRu, etc., deposited under argon gas (e.g., M2), or under a gas mixture of argon and oxygen or nitrogen (e.g., M1). Dielectric materials such as oxides, carbides or nitrides can be incorporated into the target materials also.

Embodiments of this invention include the use of any of the various magnetic alloys containing Pt and Co, and other combinations of B, Cr, Co, Pt, Ni, Al, Si, Zr, Hf, W, C, Mo, Ru, Ta, Nb, O and N, in the magnetic recording layer.

In a preferred embodiment the total thickness of SUL could be 100 to 5000 Å, and more preferably 600 to 2000 Å. There could be a more than one soft under layer. The laminations of the SUL can have identical thickness or different thickness. The spacer layers between the laminations of SUL could be Ta, C, etc. with thickness between 1 and 50 Å. The thickness of the seed layer, tₛ, could be in the range of 1 Å<tₛ<50 Å. The thickness of an intermediate layer could be 10 to 500 Å, and more preferably 100 to 300Å. The thickness of the magnetic recording layer is about 50 Å to about 300 Å, more preferably 80 to 150 Å. The adhesion enhancement layer could be Ti, TiCr, Cr etc. with thickness of 10 to 50 Å. The overcoat cap layer could be hydrogenated, nitrogenated, hybrid or other forms of carbon with thickness of 10 to 80 Å, and more preferably 20 to 60 Å.

The magnetic recording medium has a remanent coercivity of about 2000 to about 10,000 Oersted, and an Mrt (product of remanance, Mr, and magnetic recording layer thickness, t) of about 0.2 to about 2.0 memu/cm². In a preferred embodiment, the coercivity is about 2500 to about 9000 Oersted, more preferably in the range of about 4000 to about 8000 Oersted, and most preferably in the range of about 4000 to about 7000 Oersted. In a preferred embodiment, the Mᵣt is about 0.25 to about 1 memu/cm², more preferably in the range of about 0.4 to about 0.9 memu/cm².

Almost all the manufacturing of a disk media takes place in clean rooms where the amount of dust in the atmosphere is kept very low, and is strictly controlled and monitored. After one or more cleaning processes on a non-magnetic substrate, the substrate has an ultra-clean surface and is ready for the deposition of layers of magnetic media on the substrate. The apparatus for depositing all the layers needed for such media could be a static sputter system or a pass-by system, where all the layers except the lubricant are deposited sequentially inside a suitable vacuum environment.

Each of the layers constituting magnetic recording media of the present invention, except for a carbon overcoat and a lubricant topcoat layer, may be deposited or otherwise formed by any suitable physical vapor deposition technique (PVD), e.g., sputtering, or by a combination of PVD techniques, i.e., sputtering, vacuum evaporation, etc., with sputtering being preferred. The carbon overcoat is typically deposited with sputtering or ion beam deposition. The lubricant layer is typically provided as a topcoat by dipping of the medium into a bath containing a solution of the lubricant compound, followed by removal of excess liquid, as by wiping, or by a vapor lube deposition method in a vacuum environment.

Sputtering is perhaps the most important step in the whole process of creating recording media. There are two types of sputtering: pass-by sputtering and static sputtering. In pass-by sputtering, disks are passed inside a vacuum chamber, where they are deposited with the magnetic and non-magnetic materials that are deposited as one or more layers on the substrate when the disks are moving. Static sputtering uses smaller machines, and each disk is picked up and deposited individually when the disks are not moving. The layers on the disk of the embodiment of this invention were deposited by static sputtering in a sputter machine.

The sputtered layers are deposited in what are called bombs, which are loaded onto the sputtering machine. The bombs are vacuum chambers with targets on either side. The substrate is lifted into the bomb and is deposited with the sputtered material.

A layer of lube is preferably applied to the carbon surface as one of the topcoat layers on the disk.

Sputtering leads to some particulates formation on the post sputter disks. These particulates need to be removed to ensure that they do not lead to the scratching between the head and substrate. Once a layer of lube is applied, the substrates move to the buffing stage, where the substrate is polished while it preferentially spins around a spindle. The disk is wiped and a clean lube is evenly applied on the surface.

Subsequently, in some cases, the disk is prepared and tested for quality thorough a three-stage process. First, a burnishing head passes over the surface, removing any bumps (asperities as the technical term goes). The glide head then goes over the disk, checking for remaining bumps, if any. Finally the certifying head checks the surface for manufacturing defects and also measures the magnetic recording ability of the disk.

### EXAMPLES

A polished glass substrate the following layers were deposited on the substrate to make the perpendicular magnetic recording medium of an embodiment of this invention:
1. Adhesion layer: Ti, 0-100 Å.
2. SUL: Co_{100-x-y-z}—Feₓ—B_{y}—Cr_{z} (10≦x≦70, 0≦y≦30, 0≦z≦30), or Co_{100-x-y-z}-Zrₓ—Ta_{y}—Cr_{z} (x<30, y<30, z<30) or Co_{100-x-y-z}-Zrₓ—Nb_{y}—Cr_{z} (x<30, y<30, z<30); SUL thickness: single SUL: 100-5000 Å, anti-ferromagnetic coupled (AFC) SUL: bottom SUL 50-2500 Å/spacer/top SUL: 50-2500 Å.
3. Seed layer: Cu, Ag, Au, Ta; SL thickness: 1-50 Å
4. Interlayer: Ru, RuX, and/or RuXO (X═Cr, Ta, W); Interlayer thickness: 10-500 Å.
5. M1: Co_{100-x-y-z}Ptₓ(X)_{y}(MO)_{z} (X is the optional 3^{rd} additives, such as Cr. MO is dielectric components, such as SiO₂, TiO₂, Nb₂O₅, WO₃, Al₂O₃, and so on). 1≦x≦30, 0≦y≦y30, 1≦z≦30; M1 thickness 0-500 Å.
6. M2: Co_{100-x-y-z-α}CrₓPt_{y}B_{z}X_{α} (X is the optional 5^{th} additives, such as Cu, Au, Ta, V). 0≦x≦30, 0≦y≦y30, 0≦z≦30, 0≦α≦10; M2 thickness 0-500 Å.

The perpendicular magnetic recording medium of the embodiment could have a ML1 ratio=Mrt1/(Mrt1 +Mrt2)* 100%: 0% to 100%. Mrt1=the Mrt from film stack without M2 type of layers, Mrt1+Mrt2=the Mrt from the whole film stack of the designed media. Alternatively, a thickness ratio of M1=t1/(t1+t2)*100: 0% to 100%, where t1 is the thickness of M1 layers, t2 is the thickness of M2 layers.

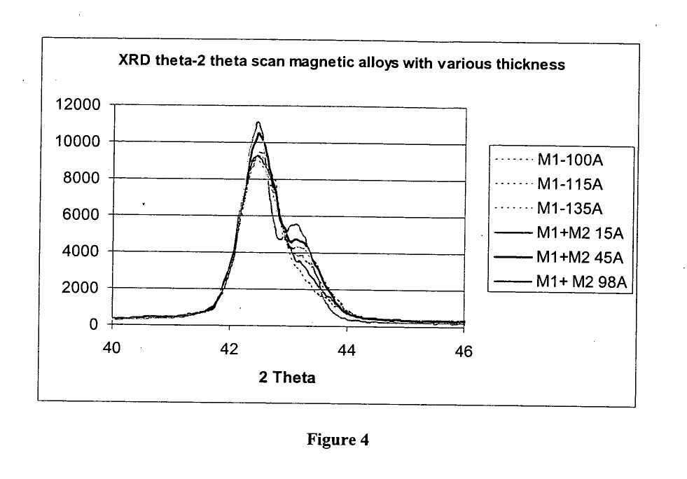

FIG. 4 provides a comparison of a two perpendicular media: a conventional granular oxide media having M1 versus an embodiment of the claimed media having M1+M2. The result show in the conventional granular oxide media, M1 has the (00.2) orientation of the Ru IL and as the thickness of M1 increases, the CoPt (00.2) peak intensity of M1 also increases. In an embodiment of the claimed media, M2 grown epitaxially from M1 unexpectedly inherited the (00.2) orientation even though M2 did not contain granular dielectric-containing grain boundary. As the thickness of M2 was increased, the CoPt (00.2) peak also increased. The XRD result proved the embodiments of the claimed media contain perpendicular anisotropy in both M1 and M2.

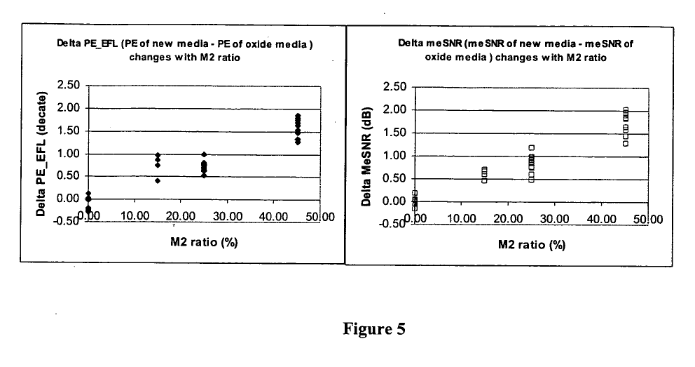

Table 1 shows examples of the parametric test result of the embodiments of the claimed media compared to a conventional granular dielectric-containing perpendicular magnetic recording media. The data in Table 1 was normalized by subtracting the Position Error_Error Floor (PE_EFL), which is a measure of BER, and media signal to noise ratio (Med eSNR) of the conventional granular dielectric-containing perpendicular magnetic recording media from those of the embodiments of the claimed media are plotted in FIG. 5, which shows that the embodiments of the claimed media a higher SNR of up to about 2 dB or decade as compared to the conventional granular dielectric-containing perpendicular magnetic recording media.

| | | | | | | | | | | | | | |
|---|---|---|---|---|---|---|---|---|---|---|---|---|---|
| | | HFTAA | LFTAA | Resol | PW50 | Rev OW | OW | | | Med | Elec | Tot | MWW |
| Disk ID | Discription | (mV) | (mV) | (%) | (uin) | (dB) | (dB) | PE_EFL | OTC_EFL | eSNR | eSNR | eSNR | (uin) |

| | | | | | | | | | | | | | |
|---|---|---|---|---|---|---|---|---|---|---|---|---|---|
| F407056-c4-1A | Oxide media | 1.494 | 2.162 | 69.08 | 2.43 | 39.27 | 39.53 | −4.40 | −4.15 | 13.13 | 24.14 | 12.80 | 5.45 |
| F410163-SAH-1A | New media, | 1.631 | 2.220 | 73.44 | 2.33 | 36.02 | 40.65 | −5.13 | −4.79 | 13.81 | 25.83 | 13.54 | 5.34 |
| | M2 ratio = | | | | | | | | | | | | |
| | 15% | | | | | | | | | | | | |
| F410163-SAH-1B | New media, | 1.642 | 2.226 | 73.78 | 2.34 | 36.46 | 40.09 | −4.78 | −4.41 | 13.59 | 25.65 | 13.33 | 5.37 |
| | M2 ratio = | | | | | | | | | | | | |
| | 15% | | | | | | | | | | | | |
| F410163-SAH-2A | New media, | 1.640 | 2.225 | 73.73 | 2.30 | 36.43 | 40.75 | −5.35 | −4.99 | 13.84 | 25.89 | 13.58 | 5.29 |
| | M2 ratio = | | | | | | | | | | | | |
| | 15% | | | | | | | | | | | | |
| F410163-SAH-2B | New media, | 1.622 | 2.209 | 73.43 | 2.34 | 36.19 | 40.33 | −5.25 | −4.67 | 13.75 | 25.70 | 13.48 | 5.23 |
| | M2 ratio = | | | | | | | | | | | | |
| | 15% | | | | | | | | | | | | |
| F407056-c4-1A | Oxide media | 1.504 | 2.180 | 68.98 | 2.42 | 38.87 | 39.61 | −4.37 | −4.14 | 13.15 | 24.36 | 12.84 | 5.37 |
| F407056-c4-1A | Oxide media | 1.469 | 2.140 | 68.65 | 2.45 | 39.15 | 39.67 | −4.36 | −4.07 | 13.12 | 24.15 | 12.79 | 5.56 |
| F410142-C88-1A | New media, | 1.520 | 2.129 | 71.39 | 2.40 | 38.61 | 39.83 | −5.05 | −4.94 | 14.05 | 24.93 | 13.71 | 5.35 |
| | M2 ratio = | | | | | | | | | | | | |
| | 25% | | | | | | | | | | | | |
| F410142-C88-1B | New media, | 1.527 | 2.137 | 71.46 | 2.38 | 38.01 | 39.79 | −5.40 | −5.23 | 14.05 | 25.00 | 13.71 | 5.27 |
| | M2 ratio = | | | | | | | | | | | | |
| | 25% | | | | | | | | | | | | |
| F410142-C89-1A | New media, | 1.473 | 2.058 | 71.56 | 2.38 | 36.98 | 41.59 | −5.20 | −4.16 | 13.89 | 24.82 | 13.55 | 5.39 |
| | M2 ratio = | | | | | | | | | | | | |
| | 25% | | | | | | | | | | | | |
| F410142-C89-1B | New media, | 1.512 | 2.094 | 72.21 | 2.38 | 37.14 | 40.94 | −5.05 | −4.36 | 13.86 | 25.10 | 13.55 | 5.26 |
| | M2 ratio = | | | | | | | | | | | | |
| | 25% | | | | | | | | | | | | |
| F407056-c4-1A | Oxide media | 1.466 | 2.145 | 68.35 | 2.46 | 39.14 | 39.49 | −4.51 | −4.12 | 13.13 | 23.92 | 12.78 | 5.44 |
| F410163SAH-7A | New media, | 1.024 | 1.517 | 67.51 | 2.66 | 32.51 | 39.31 | −5.05 | −4.95 | 13.76 | 21.77 | 13.12 | 4.94 |
| | M2 ratio = | | | | | | | | | | | | |
| | 15% | | | | | | | | | | | | |
| F410163SAH-7A | New media, | 1.013 | 1.508 | 67.18 | 2.67 | 32.18 | 41.06 | −4.94 | −4.89 | 13.67 | 21.62 | 13.03 | 4.97 |
| | M2 ratio = | | | | | | | | | | | | |
| | 15% | | | | | | | | | | | | |
| F411055-C5-2A | New media, | 1.020 | 1.607 | 63.47 | 2.69 | 40.22 | 36.30 | −5.93 | −5.60 | 14.73 | 22.18 | 14.01 | 5.30 |
| | M2 ratio = | | | | | | | | | | | | |
| | 45% | | | | | | | | | | | | |
| F411055-C5-2B | New media, | 1.036 | 1.634 | 63.43 | 2.70 | 40.29 | 36.43 | −5.63 | −5.28 | 14.59 | 22.12 | 13.88 | 5.25 |
| | M2 ratio = | | | | | | | | | | | | |
| | 45% | | | | | | | | | | | | |
| F410163SAH-7A | New media, | 1.021 | 1.527 | 66.85 | 2.66 | 32.94 | 40.84 | −5.10 | −4.99 | 13.76 | 22.30 | 13.17 | 4.98 |
| | M2 ratio = | | | | | | | | | | | | |
| | 15% | | | | | | | | | | | | |
| F410163SAH-7A | New media, | 1.007 | 1.508 | 66.79 | 2.66 | 32.67 | 40.31 | −5.05 | −4.89 | 13.80 | 22.25 | 13.20 | 4.86 |
| | M2 ratio = | | | | | | | | | | | | |
| | 15% | | | | | | | | | | | | |

PE_EFL was determined by Guzik spin-stand tester.

Med eSNR was determined by Guzik spin-stand tester.

It was found that the embodiments of the claimed media having M1+M2 achieve desired segregation with M1 containing oxide grain boundary, while still providing the desired exchange coupling by the non-oxide containing layer M2.

This application discloses several numerical ranges in the text and figures. The numerical ranges disclosed support any range or value within the disclosed numerical ranges even though a precise range limitation is not stated verbatim in the specification because this invention can be practiced throughout the disclosed numerical ranges. In the claims, the terms “a” and “an” mean one or more.

The above description is presented to enable a person skilled in the art to make and use the invention, and is provided in the context of a particular application and its requirements. Various modifications to the preferred embodiments will be readily apparent to those skilled in the art, and the generic principles defined herein may be applied to other embodiments and applications without departing from the spirit and scope of the invention. Thus, this invention is not intended to be limited to the embodiments shown, but is to be accorded the widest scope consistent with the principles and features disclosed herein. Finally, the entire disclosure of the patents and publications referred in this application are hereby incorporated herein by reference.

1. A magnetic recording medium, comprising:
a substrate,
a first magnetic layer comprising a dielectric material at a grain boundary and having a perpendicular anisotropy, and
a second magnetic layer having a perpendicular anisotropy, wherein the second magnetic layer contains substantially no oxide.

2. The magnetic recording medium of claim 1, wherein the dielectric material is selected from the group consisting of an oxide, carbide, carbon, a nitride and combinations thereof.

3. The magnetic recording medium of claim 1, wherein the second magnetic layer comprises a grain boundary that is thinner than the grain boundary of the first magnetic layer.

4. The magnetic recording medium of claim 1, wherein the first magnetic layer comprises Co_{100-x-y-z}Ptₓ(X)_{y}(MO)_{z} wherein X comprises Cr; MO is an oxide; and ranges of x, y and z are: 1≦x≦30, 0≦y≦30 and 1≦z≦30.

5. The magnetic recording medium of claim 4, wherein MO is selected from the group consisting of SiO₂, TiO₂, Nb₂O₅, WO₃, Al₂O₃, and combinations thereof.

6. The magnetic recording medium of claim 1, wherein the second magnetic layer comprises Co_{100-x-y-z-α}CrₓPt_{y}B_{z}X_{α}, wherein X is an optional additive selected from the group consisting of Cu, Au, Ta, V and combinations thereof, and ranges of x, y, z and a are: 0≦x≦30, 0≦y≦30, 0≦z≦30, 0≦α≦10.

7. The magnetic recording medium of claim 1, wherein the first magnetic layer comprises a single layer or multiple layers.

8. The magnetic recording medium of claim 1, wherein the second magnetic layer comprises a single layer or multiple layers.

9. The magnetic recording medium of claim 1, wherein the second magnetic layer comprises a grain boundary that is denser than the grain boundary of the first magnetic layer.

10. The magnetic recording medium of claim 9, wherein the grain boundary of the second magnetic layer comprises a material selected from the group consisting of Co, Pt, Cr, B and combinations thereof.

11. The magnetic recording medium of claim 1, wherein the second magnetic layer is directly on top of the first magnetic layer.

12. The magnetic recording medium of claim 1, further comprising a soft underlayer between the substrate and the first magnetic layer.

13. The magnetic recording medium of claim 1, further comprising a seedlayer and/or interlayer that grow the first magnetic layer in a Co (00.2) orientation.

14. The magnetic recording medium of claim 1, wherein the second magnetic layer has a growth orientation that is same as a growth orientation of the first magnetic layer.

15. The magnetic recording medium of claim 1, wherein the first magnetic layer has a thickness ti and the second magnetic layer has a thickness t₂, and wherein the magnetic recording medium has a higher SNR than that of another magnetic recording medium having same structure except the first magnetic layer has a thickness t₁+t₂ and the second magnetic layer has a thickness of zero.

16. A method of manufacturing a magnetic recording medium, comprising:
depositing a first magnetic layer having a perpendicular anisotropy and depositing a second magnetic layer having a perpendicular anisotropy on the first magnetic layer from a target containing substantially no oxide.

17. The method of claim 16, wherein said depositing the first magnetic layer is in an argon and oxygen containing environment having a pressure of more than 20 mTorr and said depositing the second magnetic layer is in an argon containing environment having substantially no oxygen and having a pressure of less than 20 mTorr.

18. The method of claim 16, wherein the first magnetic layer is deposited from one or more targets comprising a dielectric.

19. The method of claim 16, wherein the second magnetic layer contains substantially no oxide.
